(19) United States
(12) Patent Application Publication
(10) Pub. No.: US 2007/0153858 A1
(43) Pub. Date: Jul. 5, 2007

(54) Optical spot size converter integrated laser device and method for manufacturing the same

(75) Inventors: Young-Hyun Kim, Suwon-si (KR); In Kim, Suwon-si (KR); Eun-Hwa Lee, Suwon-si (KR); Yu-Dong Bae, Suwon-si (KR)

Correspondence Address: CHA & REITER, LLC, 210 ROUTE 4 EAST STE 103, PARAMUS, NJ, 07652, US

(73) Assignee: Samsung Electronics Co.; LTD

(21) Appl. No.: 11/523,513

(22) Filed: Sep. 19, 2006

(30) Foreign Application Priority Data
Jan. 3, 2006 (KR) 572/2006

(51) Int. Cl. H01S 5/00

(52) U.S. Cl. 372/50.1

(57) ABSTRACT

An optical spot size converter integrated laser device includes a substrate; a first waveguide laminated on the substrate and optically coupled to an optical fiber, the first waveguide being divided into a light source region having an active waveguide and an optical spot size converter region, and a trench formed on both lateral walls of the first waveguide on the substrate so that light emitted from the active waveguide interferes with light reflected by a wall surface of the first waveguide inside the first waveguide. By means of mutual interference between light emitted directly from the active waveguide of the laser device and light reflected by the interference waveguide, the optical spot size of a laser can be adjusted without affecting the single mode of the laser.

### CLAIM OF PRIORITY

This application claims priority to an application entitled “Optical Spot Size Converter Integrated Laser Device and Method for Manufacturing the Same,” filed with the Korean Intellectual Property Office on Jan. 3, 2006 and assigned Serial No. 2006-00572, the contents of which are incorporated herein by reference.

### BACKGROUND OF THE INVENTION

1. Field of the Invention

The present invention relates to a laser device integrated with an optical spot size converter (hereinafter, referred to as SSC) capable of adjusting the spot size of a laser without affecting the single mode of the laser, and a method for manufacturing the same.

2. Description of the Related Art

When it is necessary to manufacture a laser diode (LD) device, which oscillates in a single mode, for use in long-distance high-speed communication, a DFB (distributed feedback) laser diode must be constructed so that it has a diffraction grating positioned above or below an active waveguide, which generates a laser beam. To this end, it is customary to periodically vary the refractive index within the resonance length of the laser diode by using the diffraction grating. The FFP (far field pattern) of a single-mode laser created in this manner has a horizontal range of 24° and a vertical range of 32°. The optical coupling efficiency, when a package is manufactured, is about 30% in the case of a TO can using an aspheric lens. However, the high price of the aspheric lens, and of the laser package and module equipped with the lens, prevent their usage from becoming widespread.

In order to reduce the cost, it has recently become common to manufacture a TO can package equipped with an inexpensive ball lens. However, the ball lens has an optical coupling efficiency of merely about 15%, which is much inferior to that of the aspheric lens, and does not provide high output. For these reasons, the TO can package equipped with the ball lens is not suitable for long-distance transmission.

To obtain high output from a laser module while using a ball lens, it is desired that good optical coupling be established between the laser beam from a laser chip and the ball lens.

To this end, the irradiation angle of the emitted laser, i.e., the FFP, must be reduced to 10° in both horizontal and vertical directions, and various methods have been proposed for that purpose.

For a Fabry-Perot (FP) laser, a typical SSC can be made by etching a part of an active waveguide region, which is close to a light-emitting surface, in such a manner that the region becomes narrower towards the surface. The operation principle is as follows: when the width of an optical waveguide becomes smaller towards a light-emitting surface, the average effective refractive index decreases towards the light-emitting surface, because the optical waveguide has a high refractive index, while a peripheral clad has a low one. In general, light tends to be concentrated in a place having a high refractive index. When a laser propagates towards the light-emitting surface, the laser gradually spreads out, due to the gradual reduction in the average effective refractive index of the optical waveguide. As a result, the NF (near field) of the laser expands. Compared with a conventional FP LD, which maintains the same width up to the light-emitting surface of the active waveguide, an SSC FP LD, which has lateral taper, increases its NF. However, the FFP, which is a radiation angle of a laser measured at a sufficiently long distance from the light-emitting surface, is inversely proportional to the size of the NF. Consequently, for the SSC FP LD having a large NF, the FFP decreases.

In the case of a DFB LD, an SSC can be fabricated in a similar way as in the case of the FP LD, but a different type of problem occurs. The DFB LD has a diffraction grating of an active waveguide, which selects a wavelength in proportion to a peripheral effective refractive index. For this reason, the wavelength width of an oscillating laser from the DFB LD is smaller than that from the FP LD. In the case of an SSC DFB LD, which incorporates an SSC, the average effective refractive index in the SSC region gradually decreases towards the light-emitting surface, as mentioned above, and, in that region, a laser oscillates with a wavelength shorter than that of a laser from the LD. As a result, the original single wavelength from the LD is mixed with different wavelengths of light, and it is impossible to emit a single wavelength of light. In order to prevent the oscillation of a laser in the SSC, the diffraction grating must be removed from the SSC, and current injection must be interrupted so that no gain is obtained. However, the bandwidth of the SSC is identical to that of the LD in this case, and the laser from the LD is absorbed by the SSC. Therefore, light generated by the LD is absorbed, even before it is emitted from the light-emitting surface, and the laser power decreases.

In an attempt to avoid such a phenomenon, various methods have been proposed, including the following: it has been suggested that a passive waveguide be formed below an active waveguide and a diffraction grating so that a single mode of light generated in an LD region is optically coupled to the passive waveguide and the spot size is converted.

Complicating the process, however, it is difficult to form a diffraction grating above the passive waveguide and align it with the passive waveguide. The optical coupling efficiency of light from the active waveguide to the passive waveguide is poor, resulting in weak laser power.

Alternatively, it has been proposed to use SAG (selective area growth) and provide the vertical taper effect. In this case, the thickness of the light-emitting surface of the passive waveguide is smaller than that of the active waveguide, and so is the bandwidth. This causes loss of light resulting from absorption in the SSC region to be reduced.

However, the active waveguide, which has been grown by SAG so as to be thick, generally has many defects and exhibits weaker optical output than in the case of conventional epitaxial growth. In addition, a separate process for removing the diffraction grating from the SSC region lengthens the manufacturing process.

### SUMMARY OF THE INVENTION

The present invention has been made to solve the above-mentioned problems occurring in the prior art, and, in one aspect, a laser device is integrated with an optical spot size converter capable of adjusting the spot size of a laser without affecting the single mode of the laser. A method for manufacturing the same is also provided.

In a further aspect, a laser device is integrated with an optical spot size converter capable of reducing the overall FFP of the laser device and improving the optical coupling efficiency when a package is fabricated.

To realize the above aspects, there is provided, in one embodiment, an optical spot size converter integrated laser device including a substrate; a first waveguide laminated on the substrate and optically coupled to an optical fiber, the first waveguide being divided into a light source region having an active waveguide and an optical spot size converter region, and a trench formed on both lateral walls of the first waveguide on the substrate so that light emitted from the active waveguide interferes with light reflected inside the first waveguide by a wall surface of the first waveguide.

The first waveguide has a dielectric layer laminated on the substrate so that total reflection occurs on a lower surface of the first waveguide.

In realizing the above aspects, there is further provided an exemplary method for manufacturing an optical spot size converter integrated laser device including the steps of (a) laminating a lower clad layer, an active layer, and an upper clad layer successively on a semiconductor substrate; (b) forming a mask pattern in a predetermined active waveguide region on the upper clad layer and etching the upper clad layer, the active layer, the lower clad layer, and a part of the semiconductor substrate through a photolithography process to form a mesa structure; (c) forming an current interruption layer on a lateral wall of the mesa structure; and (d) etching the current interruption layer on the lateral wall in the active waveguide region to form a first waveguide and a double trench, the first waveguide including an active waveguide.

The step (a) includes a step of forming a diffraction grating on the lower clad layer.

### BRIEF DESCRIPTION OF THE DRAWINGS

The above and other aspects, features, and advantages of the present invention will be more apparent from the following detailed description taken in conjunction with the accompanying drawings, in which:

FIG. 1 briefly shows the structure of an LD integrated with an optical spot size converter according to an embodiment of the present invention;

FIG. 2 is a top view of the LD integrated with an optical spot size converter shown in FIG. 1;

FIGS. 3A to 3C show the spectrum of light outputted from the LD integrated with an optical spot size converter shown in FIG. 1;

FIG. 4 shows the NF and FF of a 1.3 μm wavelength DFB, which has an interference waveguide according to the present invention, and those of a conventional 1.3 μm wavelength DFB for comparison;

FIGS. 5A to 5B show the FFP of a 1.49 μm wavelength DFB LD, which has an interference waveguide according to the present invention, and that of a conventional 1.49 μm DFB LD for comparison;

FIGS. 6A to 6B show the change of FFP of an LD, which has an interference waveguide according to the present invention, as the temperature of the LD varies;

FIGS. 7A to 7E are sectional views taken along line A-A′ of FIG. 1 to show the steps of a method for manufacturing an LD integrated with an optical spot size converter according to an embodiment of the present invention; and

FIGS. 8 to 17 show the lateral structure of interference waveguides according to various embodiments of the present invention.

### DETAILED DESCRIPTION OF THE INVENTION

In the discussion to follow, detailed description of known functions and configurations incorporated herein is omitted for conciseness and clarity of presentation.

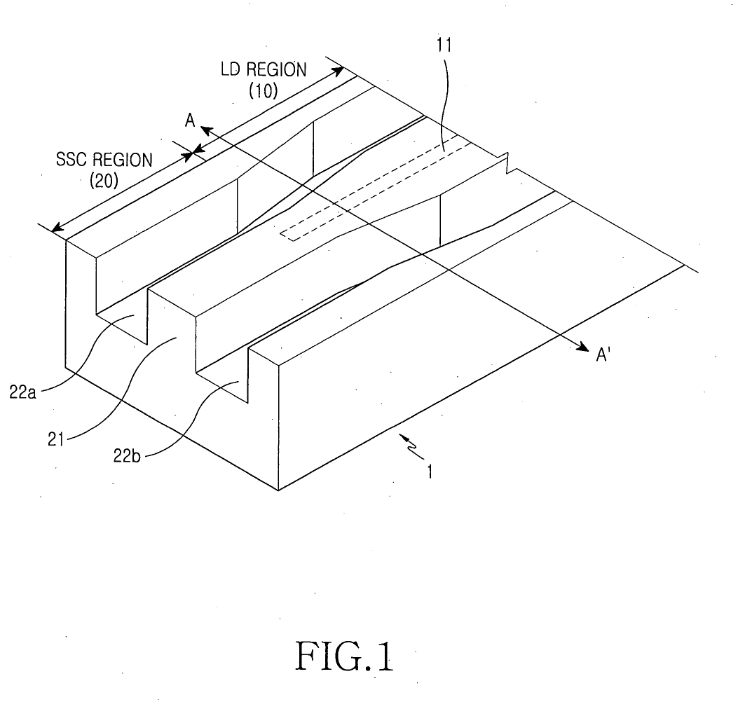

FIG. 1 briefly shows, by way of illustrative and non-limitative example, the structure of an LD 1 integrated with an optical spot size converter according to an embodiment of the present invention. The LD 1 includes an LD region 10 for generating a predetermined wavelength of laser by means of current injection, and an optical spot size conversion region 20 for converting the spot size of the laser.

The LD region 10 includes an active waveguide 11 and generates a laser by means of current injection.

The optical spot size conversion region 20 includes an interference waveguide 21 extending from an end of the active waveguide 11 so that, by means of mutual interference between light emitted directly from the active waveguide 11 and light reflected by the interference waveguide 21, the optical spot size is converted. The optical spot size conversion region 20 includes double trenches 22a, 22b formed on lateral walls of the active waveguide 11.

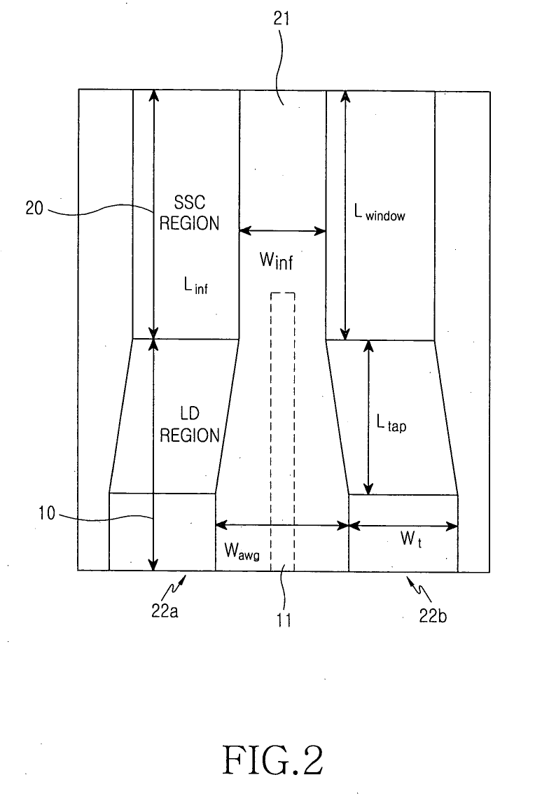

FIG. 2 is a top view of the LD 1 integrated with an optical spot size converter shown in FIG. 1. The active waveguide 11 has a width W_{awg} that preferably falls within the range 20-45 micrometers (μm). The interference waveguide 21 is positioned, width-wise, inside the W_{awg} width extent of the active waveguide to cause transverse reflection of light emitted from the active waveguide 11. Toward this objective, the interference waveguide 21 has a width W_{inf} preferably within a range from 2-12 μm. It is to be noted that the width is selected in accordance with the wavelength of the emitted laser.

The interference waveguide 21 has a length L_{inf} of about 30-100 μm so that light emitted from the front of the active waveguide 11 causes sufficient interference to achieve a desired amount of spot size conversion. The trenches 22a, 22b have a width Wₜ of approximately 20-40 μm. For example, the trenches 22a, 22b are formed by partially etching InP, which has a refractive index of 3.14, so that the created regions are filled with air and have a refractive index of 1.00. As a result, light emitted from the active waveguide 11 undergoes total reflection at the interface. Instead of using the trenches, ion implantation or ion diffusion, for example, may be used to vary the refractive index in the transverse direction and cause total reflection at the periphery of the interference waveguide.

The distance L_{window}, between an end of the active waveguide 11 and a light-emitting surface is, preferably, 20-90 μm. The larger the distance L_{window} is, the more light refracts downward (i.e. in the vertical direction). This can be used to adjust the degree of refraction of light in the vertical direction. The trenches 22a, 22b have a depth of preferably 7-15 μm, which is formed by etching, so that sufficient reflection occurs on the wall surface of the interference waveguide 21.

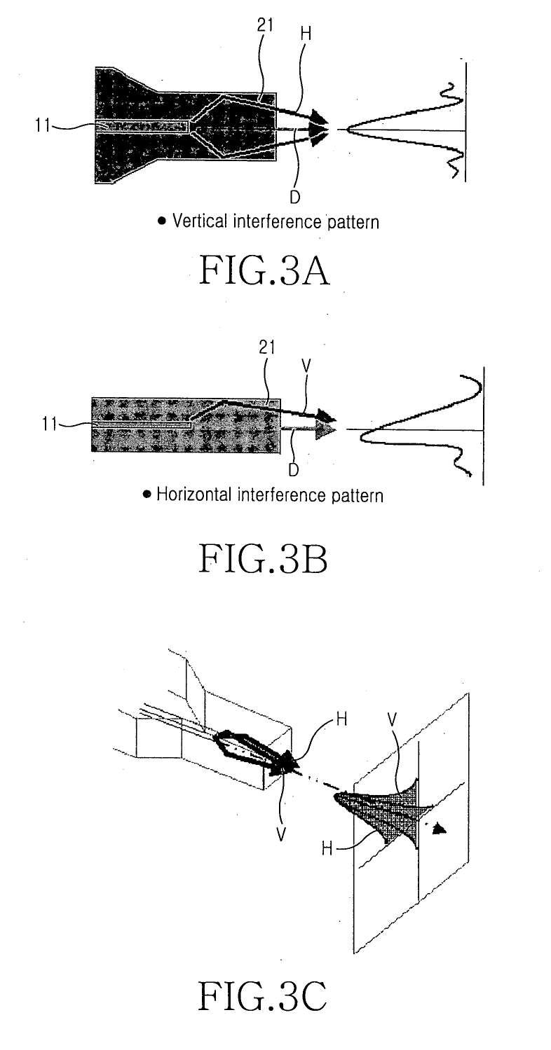

FIGS. 3A to 3C show the spectrum of light outputted from the LD 1 integrated with an optical spot size converter shown in FIG. 1. Operationally and as shown in FIG. 3A, in the case of a horizontal FFP (FFPH), light D emanating directly from the active waveguide 11 interferes with light H, which has been totally reflected by both walls of the interference waveguide 21. As a result, an interference pattern S1 is created, and the transverse width of light emitted from the light-emitting surface is reduced. Since the reflection occurring on both wall surfaces of the interference waveguide 21 is symmetrical, emitted light has symmetry in the horizontal direction.

As shown in FIG. 3B, in the case of a vertical FFP (FFPV), light D emanating directly from the active waveguide 11 interferes with light V, which has been totally reflected by the upper wall of the interference waveguide 21. As a result, the vertical width of light emitted from the light-emitting surface is reduced. Since the reflection occurs only on the upper wall in the case of vertical interference, the resulting light is emitted at a downward angle of about 2-8°.

FIG. 3 shows the horizontal and vertical FFPs together. V indicates the result of vertical reflection and interference, and H indicates the result of horizontal reflection and interference.

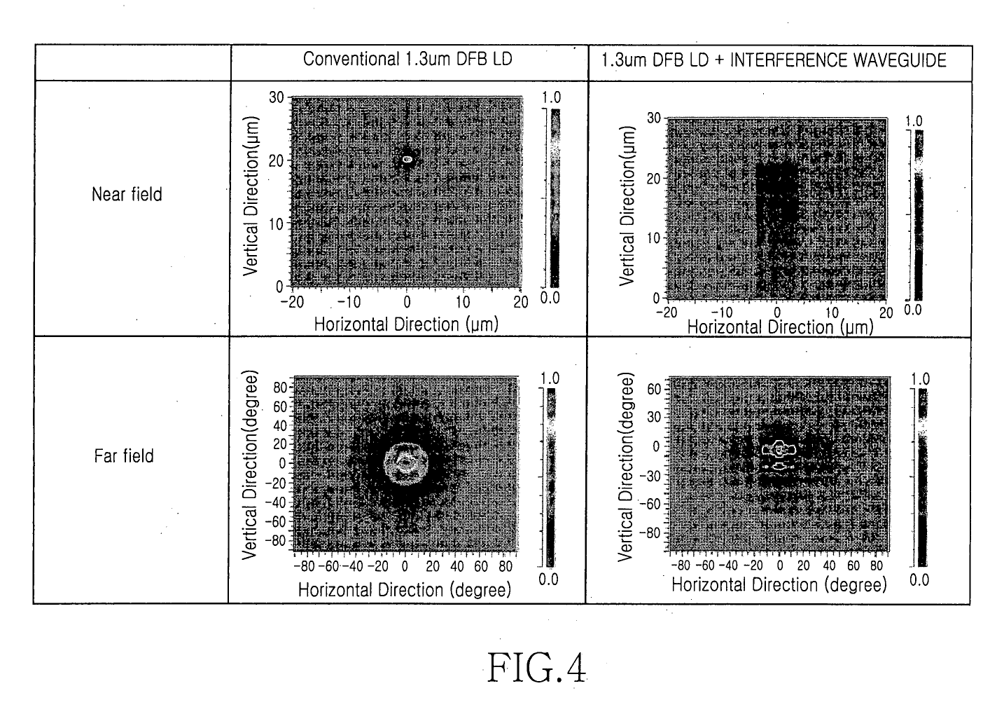

FIG. 4 shows the NF and FF of a 1.3 μm wavelength DFB LD 1, which has an interference waveguide according to the present invention, and those of a conventional 1.3 μm wavelength DFB LD for comparison.

As shown in FIG. 4, in the case of a conventional 1.30 μm wavelength DFB LD, the NF is concentrated in the vicinity of the active waveguide and has a size of about 2 μm. When the NF is small as in this case, the FF is large. The angular ratio is: FFPH/FFPV=28.0°/33.0°.

In the case of the interference waveguide, by contrast, light diffused inside the interference waveguide 21 undergoes interference. Regarding the overall size of the resulting multiple modes, the width is 8 μm. The height gradually weakens downward to a magnitude of about 8 μm. The ratio of FFPs is: FFPH/FFPV=10.0°/10.1°.

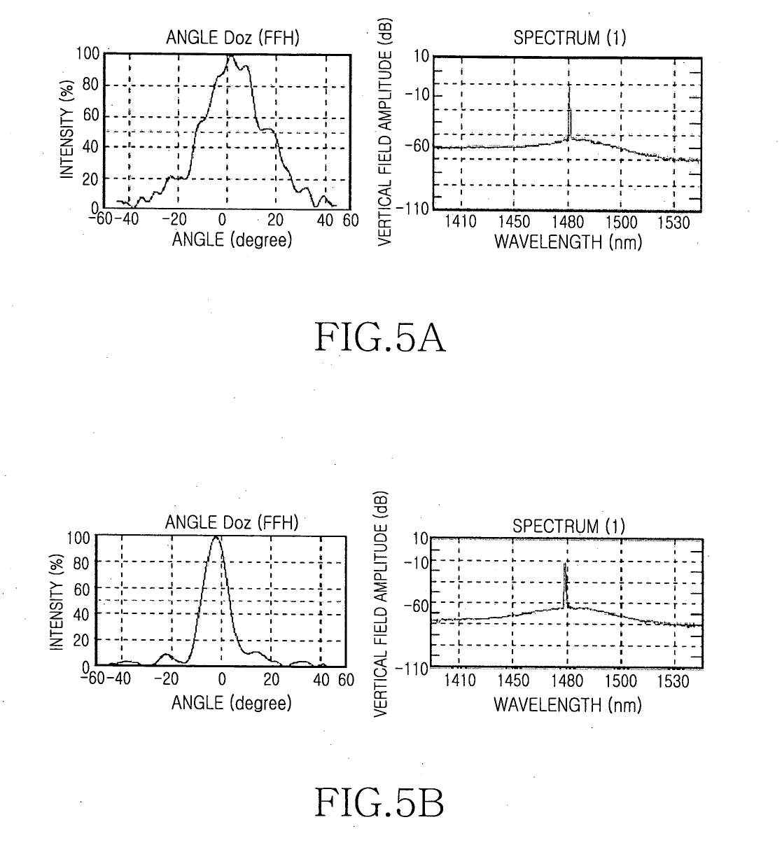

FIG. 5A shows the FFP of a 1.49 μm wavelength DFB LD, which has an interference waveguide according to the present invention, and FIG. 5B shows the FFP of a conventional 1.49 μm DFB LD. It is clear from the drawing that, due to the influence of the interference waveguide, the horizontal FFP (FFPH) has decreased from 27° to 10°, and the vertical FFP (FFPV) has decreased from 30° to 10.1°.

In an experiment, a ball lens (f=1.5 mm, BK-7, n=1.5168) was used to manufacture a TO can, and the optical coupling efficiency with regard to single-mode glass fiber was measured. The result showed that, in the case of a conventional 1.49 μm DFB, the efficiency was 17% and, in the case of a 1.47 μm DFB having an interference waveguide, the efficiency was improved to 35%.

It is clear from analysis of the spectrum that, when an interference waveguide is used, the amount of light reflected by the light-emitting surface and redirected into the active waveguide is reduced by about 100 times. In addition, the single-mode oscillation properties of the DFB improve, and the side-mode suppression ratio increases. Comparison of mean values of 30 chips has shown that, when measurement was performed near the critical current, there was an improvement of about 1.3 dB from 20.7 dB to 22.0 Db. When the laser power was 15 mW, there was an improvement of about 2.5 dB from 35 dB to 37.5 dB.

Considering that the refractive index of InP, which constitutes the interference waveguide, varies depending on the temperature, the change of FFPs was observed with regard to temperature.

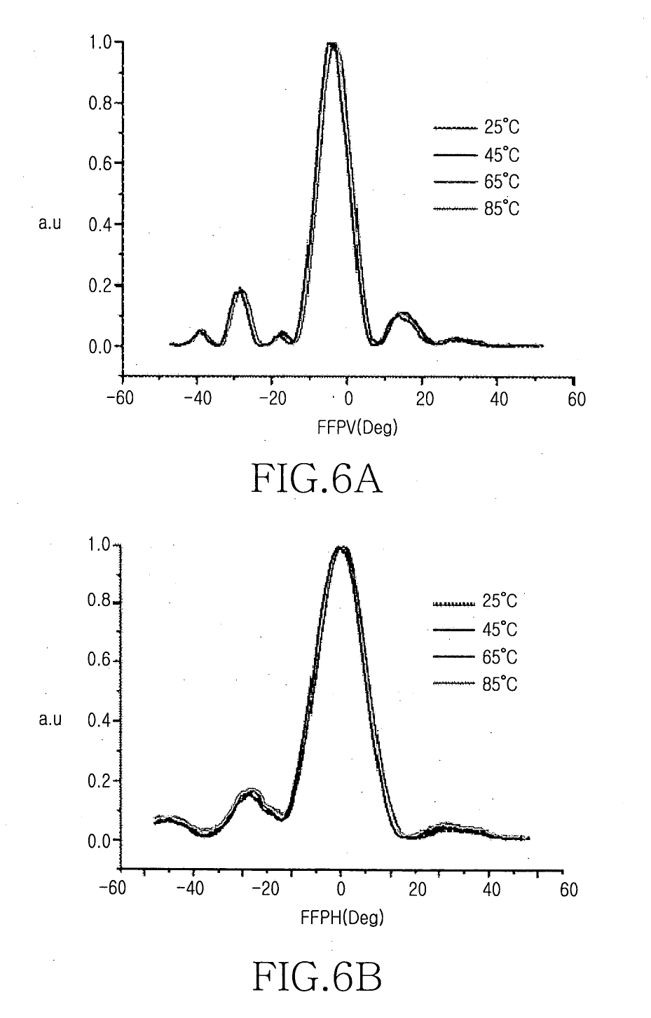

FIGS. 6A to 6B show the change of FFPs while varying the temperature from 25° C. to 85° C. in steps of 20° C. In the FFPV, there was, as seen from FIG. 6A, a change of about 1° C. In the FFPH, there was, as seen from FIG. 6B, a change of about 0.7° C. These changes lie within the limit of measurement error of the equipment. Accordingly, no variation with temperature is detected.

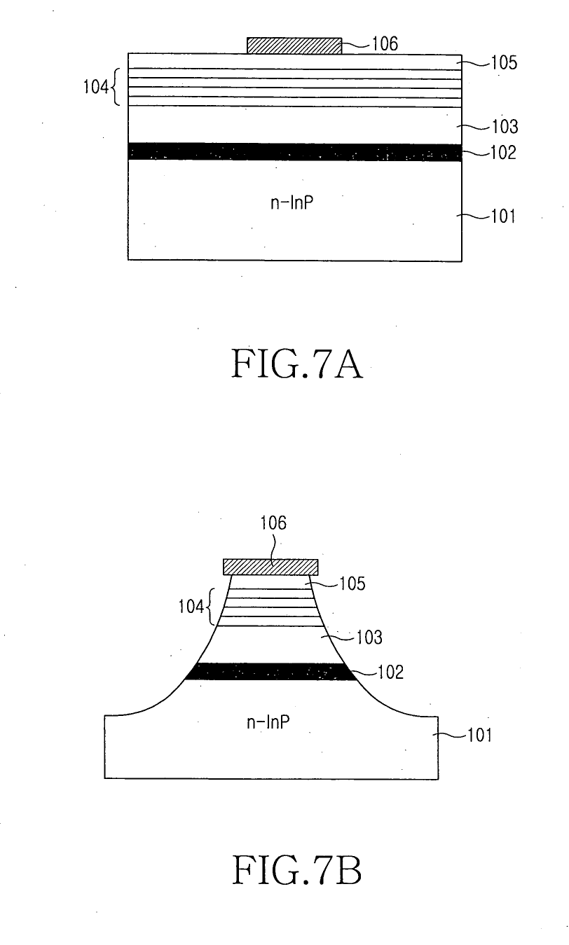

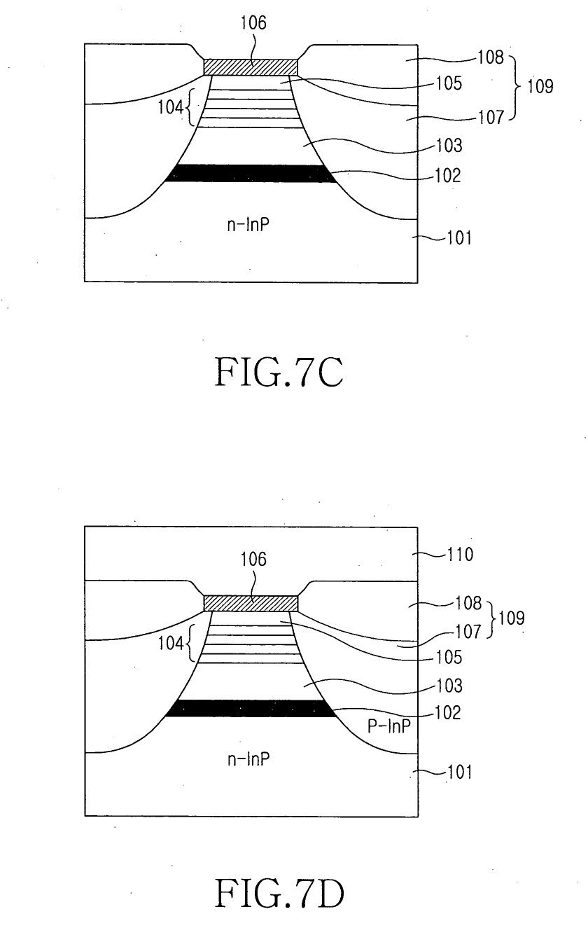

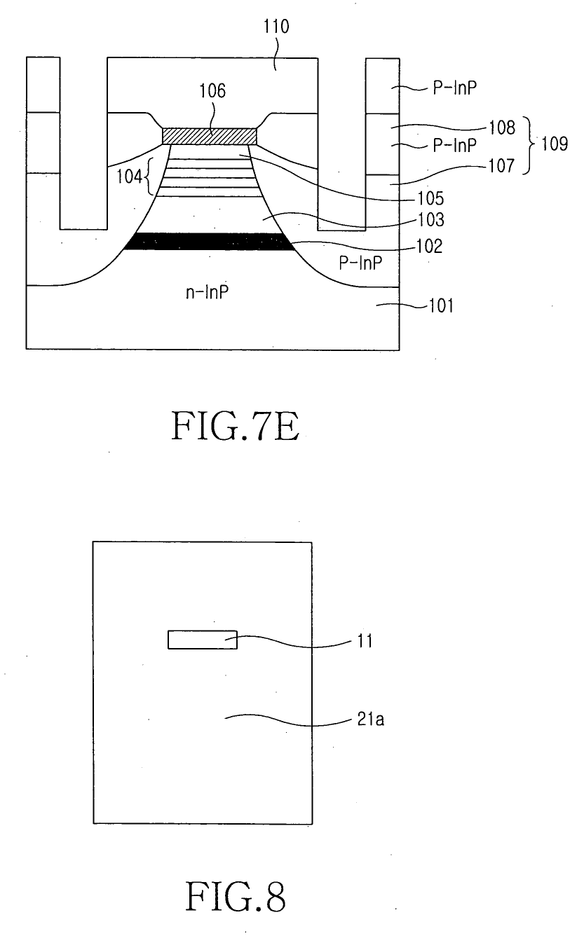

FIGS. 7A to 7E are sectional views taken along line A-A′ of FIG. 1, and an exemplary method for manufacturing the LD 1 integrated with an optical spot size converter according to an embodiment of the present invention is described below with reference to the drawings.

Referring to FIG. 7a, an InGaAsP layer is formed on an n-InP substrate 101 in a suitable method (e.g. MOCVD or MBE), in order to make a diffraction grating 102. The InGaAsP layer is grown to a thickness of 100-200 angstroms (A) using InGaAsP, which has a composition corresponding to the wavelength 1.2 μm, i.e., a composition of 1.2 Q, for the purpose of a 1.3 μm wavelength DFB. In order to protect the InGaAsP layer, an N-InP layer is grown to a thickness of 50 Å. A diffraction grating 102 having a frequency based on a predetermined wavelength is formed from the n-InP layer and the InGaAsP layer in a holographic method or by using an electron beam (e-beam).

An n-InP layer 103 is grown on the diffraction grating 102 to a thickness of 600-1500 Å so as to fill and flatten the diffraction grating. An MQW (multiple quantum well) 104 is grown thereon by using InGaAsP, which has a composition of 1.05 Q, and alternately laminating a separate confinement heterostructure (SCH) of thickness 500 Å. Inside the MQW, there are a barrier of 1.0 Q with a thickness of 130 Å and a well of 1.3 Q with a thickness of 90 Å. A p-InP layer 105 is grown on the MQW 104 to a thickness of 5000 Å, in order to facilitate current implantation. Then, SiO₂ is deposited on the p-InP layer 105 and is etched through a conventional photolithography process, in order to form an etching mask 106 for providing the LD 1 with the active waveguide 11. The etching mask 106 has a width of about 5 μm and, when the entire length of the chip is 400 μm, a length of about 360 μm.

Referring to FIG. 7B, the etching mask 106, which is made of SiO₂, is used to etch the p-InP layer 105, the MQW 104, the n-InP layer 103, the diffraction grating 102, and the n-InP substrate 101. Preferably, dry or wet etching is performed to etch them to an overall etching depth of 4-6 μm in such a manner that the n-InP substrate 101, which is positioned beneath the diffraction grating 102, is partially etched to form a mesa structure.

Referring to FIG. 7C, after forming the mesa structure, a current interruption layer 109 is formed by filling the periphery of the mesa structure with a p-InP layer 107 to a thickness of 1.5 μm and an n-InP layer 108 to a thickness of 3.5 μm, for the sake of flattening and preventing current dispersion.

Referring to FIG. 7D, the SiO₂ etching mask 106 is removed, and a p-InP layer 110 for current implantation is grown in a suitable method (e.g. MOCVD). The thickness is selected preferably from 2.5-8 μm, considering the resistance and FFP. Although not shown in the drawing, an InGaAs contact layer may be formed on the p-InP layer 110 to a thickness of about 0.5 cm, in order to facilitate ohmic contact.

Referring to FIG. 7E, the p-InP layer 110 and the current interruption layer 109 are etched near the active waveguide 11 in a double trench, in order to reduce the electrostatic capacity. The double trenches 22a, 22b are deep enough to reach the current interruption p-InP layer, which surrounds the mesa. In general, the double trenches have a depth of about 7 μm, when the p-InP layer has been grown to a thickness of 2.5 μm in the step shown in FIG. 7d, and a depth of about 13 μm when the p-InP layer has been grown to a thickness of 8 μm.

The interference waveguide 21 is made in a region where the active waveguide 11 does not exist, by etching the double trenches 22a, 22b with a small width Wt so that light emitted from the active waveguide can undergo interference. The interference waveguide has a width of 6-12 μm in the case of a DFB LD 1 having a wavelength of 1.3 μm, 8-14 μm in the case of a DFB LD having a wavelength of 1.49 μm, and 8-14 μm in the case of a DFB LD having a wavelength of 1.55 μm. The difference in wavelength between the 1.49 μm DFB and the 1.55 μm DFB is insignificant, and the width of the interference waveguide 21 has the same value.

Although the interference waveguide 21 is made of InP in the present embodiment, it may be made of a semiconductor (e.g. InP, GaAs, InGaAsP, InGaAs, Si, or Ge), a dielectric substance (SiO₂, SiNₓ, or Al₂O₃), which is formed by deposition or coating, or a polymer. Preferably, the interference waveguide is made of a material having a refractive index of 1.2-4.2 so that the NF can be enlarged and adjusted.

The interference waveguide according to the present invention can be coupled to various types of light sources, including a DFB LD, an FP LD, an EM (electro-absorption modulated) LD, and a distributed Bragg reflector (DBR) LD.

It is also possible to increase the NF size of the laser by tapering the passive optical waveguide. When the NF increases, reflection occurs on the wall surface in spite of a large width of the interference waveguide. This provides an interference effect. The fact that the distance between the wall surfaces of the active and interference waveguides 11, 21 can be increased improves the reliability.

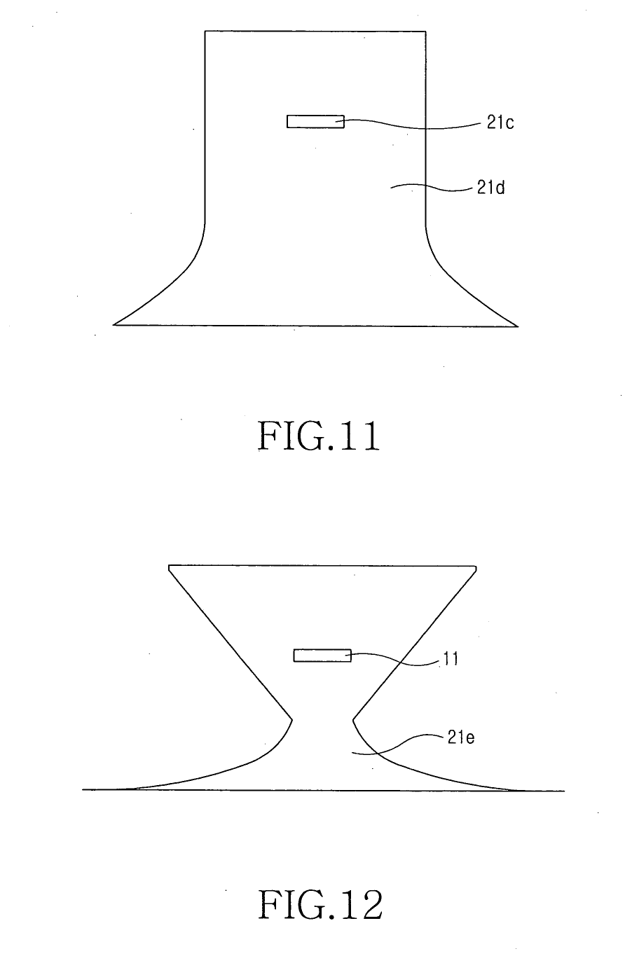

The interference waveguide 21 according to the present invention may have various shapes. FIGS. 8 to 17 show possible realizations for the sectional structure of interference waveguides near the optical output side. Each view is a cross-sectional cut, or cross-section, perpendicular to the longitudinal direction of the active and interference waveguides 11, 21. FIG. 8 shows an interference waveguide 21a having both walls positioned vertically, in order to facilitate horizontal reflection. In this case, vertical reflection occurs only on the upper surface, and emitted light is deflected downwards. In general, when the device is a 1.3 μm DFB made of InP and the p-cladding on the active waveguide 11 has a thickness of 2.5 μm, light is emitted at a downward angle of about 8° and, if the thickness of 2.5 μm, at a downward angle of about 4°. When the device is a 1.55 μm wavelength DFB and the thickness of 2.5 μm, the downward angle is about 7° and, if the thickness is 4 μm, the angle is about 2°.

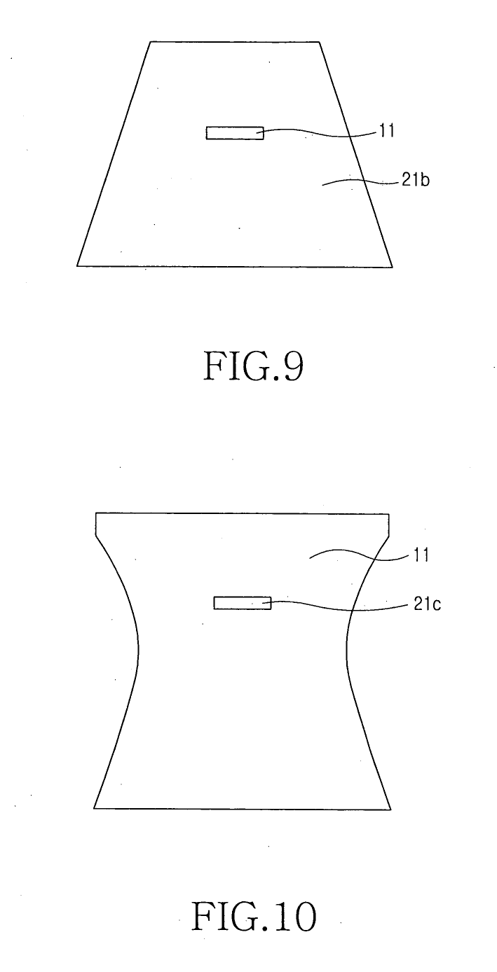

FIG. 9 shows an interference waveguide 21b having slanted wall surfaces (i.e. mesa structure) so that, when reflected horizontally, light gathers below the active waveguide 11. The slanted wall surfaces are used when light must be directed more downwards than in the case of the interference waveguide 21a shown in FIG. 8, which has vertical wall surfaces. When the wall surfaces have a slant of 89°, light is emitted at a downward angle increased by 3°. The mesa structure can be formed through a wet etching process using a solution including Br⁻ and Cl⁻ ions.

FIG. 10 shows an interference waveguide 21c having concave wall surfaces (i.e., in a saddle shape) formed in the same level as the active region 11 through a wet or dry etching process. When dry etching is used, the proportion of Cl₂ within the reaction gas is increased, the pressure inside the chamber is raised at least to 100 milliTorr (mTorr), and less bias is applied so that most etching occurs in the horizontal direction.

FIG. 1 shows an interference waveguide 21d having smooth curves formed where the vertical wall surfaces meet the underlying substrate. This increases the mechanical strength of the interference waveguide 21d. The curves are made by etching the interference waveguide 21d vertically through a dry etching process and etching it horizontally so as to reduce the width through a wet etching process.

FIG. 12 shows an interference waveguide 21e having upper wall surfaces formed in a reverse mesa structure so that reflection occurring on the reverse mesa surfaces is used to prevent the FFPV from shifting downward. The angle of the wall surfaces of the interference waveguide 21e relative to the horizontal direction is 54°, which depends on the crystal surface of the InP substrate. In order to obtain a distance of 8 μm between the active waveguide 11 and the wall surfaces in the same horizontal position as the active waveguide, the upper width must be 14 μm and the width of the lower portion must be positioned at a distance of 9.5 cm from above, when the upper p-cladding has a thickness of 4 μm. The reverse mesa structure is obtained through a wet etching process using a mixed solution of HBr and H₂O₂ as the etching agent. The etching rate is adjusted in accordance with the density of added H₂O.

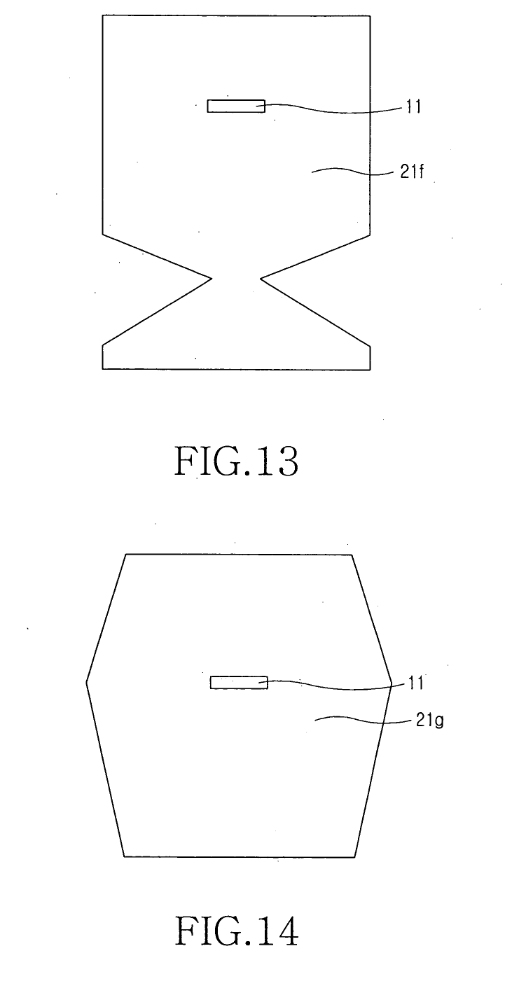

FIG. 13 shows an interference waveguide 21f having wall surfaces positioned vertically at the same level as the active waveguide 11 but narrowed at a lower level. Reflection, occurring on the reverse mesa surfaces, induces upward reflection, i.e. prevents the FFPV from shifting downwards. Wet etching is performed so as to form the reverse mesa surfaces, and dry etching is performed in the vertical direction.

FIG. 14 shows an interference waveguide 21g having upper and lower slanted surfaces positioned so as to intersect with each other at the same level as the active waveguide 11. The slanted surfaces are formed by using tilted ion beam etching.

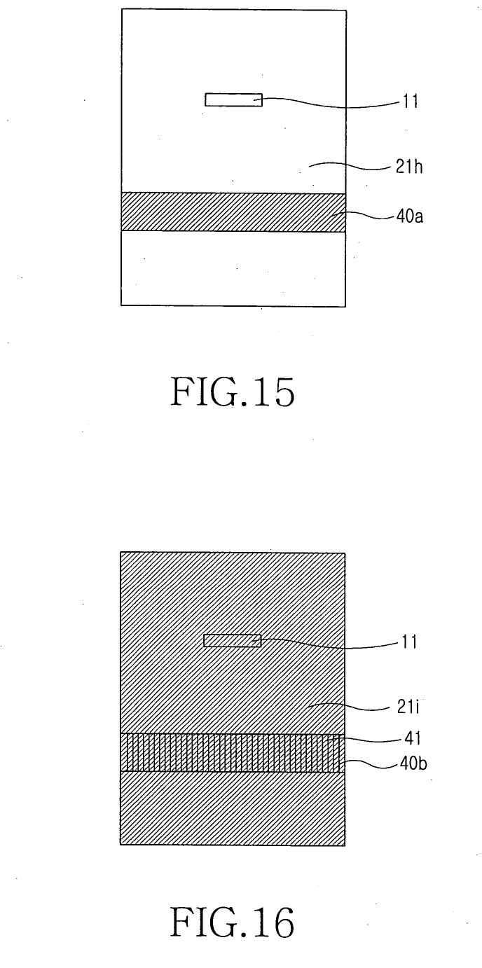

FIG. 15 shows an interference waveguide 21h having dielectric film 40a made of SiO₂, SiNₓ, or Al₂O₃, for example, and positioned on a lower surface thereof. This causes total reflection even on the lower surface of the interference waveguide 21h and prevents the FFPV from shifting downwards.

The dielectric film can be formed in one of two methods. According to the first method, as shown in FIG. 15, semiconductor layers of AlAs and InGaAs, which can be oxide film of Al compound when oxidized, are alternately stacked up to 5000 Å; InP is grown thereon with a large thickness; the interference waveguide is etched; and an oxidation process is performed to obtain oxide film 40a of Al compound.

According to the second method, as shown in FIG. 16, a number of thin rods are fabricated from a dielectric substance with a width of 0.1-1 μm and arranged. Then, InP 41 is grown in such a manner that InP grows on InP, which is exposed between the dielectric rods 40b, in both longitudinal and transverse directions while filling the gap. Since a layer grown in this manner includes dielectric substances between InP, the effective refractive index of the layer is smaller than that of InP. As a result, total reflection occurs.

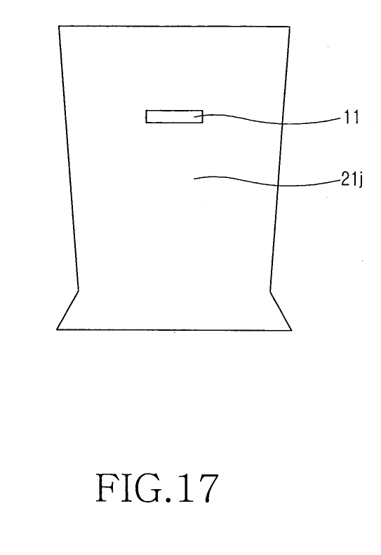

FIG. 17 shows an interference waveguide 21j having wall surfaces inclined at an angle of about 89°. The width of the lower portion of the interference waveguide 21j is smaller than that of the upper portion thereof. As a result, light is directed upwards after being reflected by the wall surfaces. Compared with the interference waveguide 21, 21a, 21c, 21f, 21h, 21j having vertical wall surfaces, light emitted in the vertical direction deflects at a downward angle smaller by 1°. The interference waveguide 21j according to the present embodiment may be formed through a wet etching process and, when the interference waveguide is made of InP, a mixed solution of HBr and H₂O is used as the etching agent.

As mentioned above, according to the present invention, the optical spot size can be easily converted by mutual interaction between light emitted directly from the active optical waveguide 11 of the laser device and light reflected by the interference waveguide 21, 21a-h. Therefore, the present invention has the following advantages:

Firstly, in terms of optical coupling efficiency with regard to a single-mode optical fiber, a DFB LD equipped with the interference waveguide 21, 21a-h according to the present invention has an optical coupling efficiency of 35%, which is substantially improved from 17% corresponding to a conventional DFB LD.

Secondly, the amount of light reflected by the light-emitting surface and redirected towards the active waveguide 11 is reduced by 1/100. This improves the single-mode oscillation properties of the LD.

Thirdly, the interference waveguide can be easily fabricated by etching the epitaxial structure of lateral walls of the active optical waveguide 11 and forming trenches 22a, 22b.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. An optical spot size converter integrated laser device comprising:
a substrate;
a first waveguide laminated on the substrate and optically coupled to an optical fiber, the first waveguide being divided into a light source region having an active waveguide and an optical spot size converter region, the first waveguide having two lateral walls with corresponding surfaces; and
two trenchs, each formed on a respective one of said lateral walls so that light emitted from the active waveguide interferes with light reflected inside the first waveguide by surface from among said corresponding surfaces.

2. The optical spot size converter integrated laser device as claimed in claim 1, wherein the first waveguide has a width within a range from 2-12 μm, said region being disposed, width-wise, inside a width extent of the active waveguide so that light emitted from the active waveguide undergoes interference horizontally.

3. The optical spot size converter integrated laser device as claimed in claim 1, wherein the first waveguide has a length within a range from 30-100 μm in an optical axis direction from an optical output surface of the active waveguide, a magnitude of said length causing light emitted from the active waveguide to undergo sufficient interference horizontally to achieve a desired amount of spot size conversion.

4. The optical spot size converter integrated laser device as claimed in claim 1, wherein the first waveguide has a height of 1.5-6 μm above the active waveguide in a direction perpendicular to an optical axis, so that light emitted from the active waveguide undergoes a desired amount of interference vertically.

5. The optical spot size converter integrated laser device as claimed in claim 1, wherein the first waveguide is made of a material having a refractive index within a range from 1.2-4.2, so that a near field of light emitted from the active waveguide is easily adjustable.

6. The optical spot size converter integrated laser device as claimed in claim 5, wherein the first waveguide is made of a combination of:
a semiconductor selected from InP, GaAs, InGaAsP, InGaAs, Si, and Ge;
a dielectric substance selected from SiO₂, SiNₓ, and Al₂O₃ and formed by deposition or coating; and
a polymer.

7. The optical spot size converter integrated laser device as claimed in claim 1, wherein a depth of a trench from among said trenches falls within a range from 7-15 μm so that sufficient reflection occurs on said surface to afford a desired amount of spot size conversion.

8. The optical spot size converter integrated laser device as claimed in claim 1, wherein the first waveguide has a dielectric layer laminated on the substrate so that total reflection occurs on a lower surface of the first waveguide.

9. The optical spot size converter integrated laser device as claimed in claim 1, comprising at least one of a DFB LD (Distributed Feedback LD), an FP LD, an EMLD (Electro-absorption Modulated LD), and a distributed Bragg reflector (DBR) LD.

10. The optical spot size converter integrated laser device as claimed in claim 1, wherein an optical output side section of the first waveguide has a rectangular cross-section perpendicular to a longitudinal direction of the first waveguide.

11. The optical spot size converter integrated laser device as claimed in claim 1, wherein an optical output side section of the first waveguide has a trapezoidal cross-section perpendicular to a longitudinal direction of the first waveguide.

12. The optical spot size converter integrated laser device as claimed in claim 1, wherein an optical output side section of the first waveguide has a saddle shape cross-section perpendicular to a longitudinal direction of the first waveguide, the cross-section having lateral sides indented at a level identical to a level of the active waveguide.

13. The optical spot size converter integrated laser device as claimed in claim 1, wherein the first waveguide has an optical output side section configured so that, in a cross-section perpendicular to a longitudinal direction of the first waveguide, said corresponding surfaces meet the substrate along curved lines, the substrate being positioned below said corresponding surfaces.

14. The optical spot size converter integrated laser device as claimed in claim 1, wherein the first waveguide has an optical output side section configured so that, in a cross-section perpendicular to a longitudinal direction of the first waveguide, said corresponding surfaces are slanted so as to intersect with each other at a level identical to a level of the active waveguide.

15. An optical spot size converter integrated laser device comprising:
a substrate;
a first waveguide laminated on the substrate and optically coupled to an optical fiber, the first waveguide being divided into a light source region having an active waveguide and an optical spot size converter region, the first waveguide having two lateral walls, each of the two having a corresponding surface; and
two total reflection regions formed on the two lateral walls, respectively, each of the two total reflection regions having a refractive index different from a refractive index of the first waveguide so that light emitted from the active waveguide interferes with light reflected inside the first waveguide by a surface from among said corresponding surfaces.

16. The optical spot size converter integrated laser device as claimed in claim 15, wherein a given one of the total reflection regions comprises at least one of an ion implantation region, an ion diffusion region, and an air layer.

17. A method for manufacturing an optical spot size converter integrated laser device comprising the acts of:
(a) laminating a lower clad layer, an active layer, and an upper clad layer successively on a semiconductor substrate;
(b) forming a mask pattern in a predetermined active waveguide region on the upper clad layer and etching the upper clad layer, the active layer, the lower clad layer, and a part of the semiconductor substrate through a photolithography process to form a mesa structure that has a lateral wall;
(c) forming an current interruption layer on said lateral wall; and
(d) etching the current interruption layer on the lateral wall in the active waveguide region to form a first waveguide and a double trench, the first waveguide including an active waveguide.

18. The method for manufacturing an optical spot size converter integrated laser device as claimed in claim 17, wherein the act (a) comprises an act of forming a diffraction grating on the lower clad layer.

19. The method for manufacturing an optical spot size converter integrated laser device as claimed in claim 17, wherein the first waveguide extends 30-100 μm in an optical axis direction from an optical output surface of the active waveguide.

20. The method for manufacturing an optical spot size converter integrated laser device as claimed in claim 19, wherein the first waveguide has a width of 2-12 μm.

21. The method for manufacturing an optical spot size converter integrated laser device as claimed in claim 18, wherein the first waveguide has a height of 1.5-6 μm above the active waveguide in a direction perpendicular to an optical axis so that light emitted from the active waveguide undergoes a desired amount of interference vertically.

22. The method for manufacturing an optical spot size converter integrated laser device as claimed in claim 17, wherein the first waveguide is made of a material having a refractive index of 1.2-4.2 so that a near field of light emitted from the active waveguide is easily enlargeable.

23. The method for manufacturing an optical spot size converter integrated laser device as claimed in claim 22, wherein the first waveguide is made of a combination of a semiconductor selected from InP, GaAs, InGaAsP, InGaAs, Si, and Ge, a dielectric substance selected from SiO₂, SiNₓ, and Al₂O₃ and formed by deposition or coating, and a polymer.

24. The method for manufacturing an optical spot size converter integrated laser device as claimed in claim 18, wherein the trench has a depth within a range from 7-15 μm.
